(19) United States
(12) Patent Application Publication
(10) Pub. No.: US 2013/0082246 A1
(43) Pub. Date: Apr. 4, 2013

(54) DISPLAY UNIT

(71) Applicant: CANON KABUSHIKI KAISHA, Tokyo (JP)

(72) Inventor: Toshinori Hasegawa, Yokohama-shi (JP)

(73) Assignee: CANON KABUSHIKI KAISHA, Tokyo (JP)

(21) Appl. No.: 13/625,168

(22) Filed: Sep. 24, 2012

(30) Foreign Application Priority Data
Sep. 29, 2011 (JP) 2011-215069

(51) Int. Cl. H01L 51/52

(52) U.S. Cl. 257/40; 257/89; 257/E51.018

(57) ABSTRACT

A display unit having satisfactory emission characteristics can be produced more easily and stably. Organic light emitting devices comprise an organic compound layer including at least a first and a second light emitting layer common in the respective organic devices. A layer constituting the organic layer has the same thickness in all the organic devices. The first layer contains a first and a second light emission dopant which are different in an emission color, a light emission spectrum, and a light emitting position in a thickness direction. The second layer contains a third light emission dopant different from the first and the second dopant in the emission color and the light emission spectrum. In at least two kinds of dopants, a distance between the first electrode and the light emitting position in the thickness direction satisfies an optical constructive condition in optical interference.

### BACKGROUND OF THE INVENTION

1. Field of the Invention

The present invention relates to a display unit, and more particularly, to a display unit using an organic light emitting device (organic electroluminescence device; hereinafter sometimes simply referred to as “device”).

2. Description of the Related Art

At present, an organic light emitting device has been extensively researched and developed. Such an organic light emitting device is an electronic device including a pair of electrodes made of an anode and a cathode, and multiple organic compound layers which include at least an emission layer and are provided between the pair of electrodes.

In recent years, as a display unit to replace a cathode-ray tube (CRT) or a liquid crystal display (LCD) used conventionally, a display unit that exhibits multiple emission colors using multiple organic light emitting devices having different emission colors are drawing attention. The display unit using an organic light emitting device exhibits excellent performance regarding contrast and color reproducibility.

An example of a full-color light emitting unit using an organic light emitting device is an organic light emitting unit using an organic light emitting device for emitting white light. Specifically, this display unit uses a system in which multiple organic light emitting devices for emitting white light are formed uniformly in the unit, and white light beams output from the organic light emitting devices are converted into light of three primary colors (red, green, and blue) by a light converting member such as a color filter.

As a specific example of the organic light emitting unit using an organic light emitting device for emitting white light, Japanese Patent Application Laid-Open No. 2005-093401 proposes a display unit. The display unit has a configuration in which a transparent barrier layer is placed on a reflective layer provided on a substrate side, and the thickness of the transparent barrier layer is set appropriately depending on the color of light emitted from an organic light emitting device. Accordingly, due to a resonance structure in which an optical interference condition varying for each color of light emitted from the organic light emitting device is satisfied in spite of the configuration in which light emitting layers constituting respective organic light emitting devices are uniform, light of red, green and blue can be output efficiently.

However, in the display unit proposed by Japanese Patent Application Laid-Open No. 2005-093401, it is necessary to change a thickness of the transparent barrier layer provided on the reflective layer for each emission color of light to be emitted. In order to change the thickness of the transparent barrier layer, it is necessary to add the step of photolithography during the production of a substrate and repeat patterning and etching multiple times. This complicates the process, with the result that the throughput of the production of the display unit is low.

### SUMMARY OF THE INVENTION

The present invention has been made so as to solve the above-mentioned problem, and it is an object of the present invention to provide a display unit having satisfactory emission characteristics and capable of being produced easily and stably.

According to an exemplary embodiment of the present invention, there is provided a display unit, including multiple organic light emitting devices on a substrate, in which each of the organic light emitting devices includes a first electrode, a second electrode, and an organic compound layer which is sandwiched between the first electrode and the second electrode and includes at least a first light emitting layer and a second light emitting layer, in which the first light emitting layer and the second light emitting layer are continuously provided in the multiple organic light emitting devices, in which the first light emitting layer contains a first light emission dopant for emitting light of a first color and a second light emission dopant for emitting light of a second color different from the first color, and a light emitting position of the light of the first color is different from a light emitting position of the light of the second color in a thickness direction, in which the second light emitting layer contains a third light emission dopant for emitting light of a third color different from the first color and the second color, and in which an optical length from the first electrode to the light emitting position satisfies a resonance condition regarding light beams of at least two colors of the first color, the second color, and the third color.

According to the present invention, the display unit having satisfactory emission characteristics and capable of being produced easily and stably can be provided. Specifically, in the display unit of the present invention, the organic light emitting devices having a uniform structure are formed in the display unit, and the resonance condition can be satisfied simultaneously with respect to light beams of multiple (at least two) colors.

Further features of the present invention will become apparent from the following description of exemplary embodiments with reference to the attached drawings.

### BRIEF DESCRIPTION OF THE DRAWINGS

FIG. 1 is a schematic cross-sectional view illustrating an example of a display unit according to an embodiment of the present invention.

FIG. 2 is a schematic cross-sectional view illustrating a light emitting position of each light emission dopant in a thickness direction in an organic light emitting device constituting the display unit of FIG. 1.

FIG. 3 is a schematic cross-sectional view illustrating a modified example of FIG. 2.

FIG. 4 is a graph showing spectral transmission characteristics of a color filter of a display unit produced in an example of the present invention.

### DESCRIPTION OF THE EMBODIMENTS

A display unit of the present invention is the one in which multiple organic light emitting devices are provided on a substrate. Herein, each organic light emitting device constituting the display unit of the present invention includes a first electrode, a second electrode, and an organic compound layer which includes at least a first light emitting layer and a second light emitting layer and is sandwiched between the first electrode and the second electrode. Layers constituting the organic compound layer are continuously provided in all the organic light emitting devices. Note that, the relative position of the two kinds of light emitting layers (first light emitting layer, second light emitting layer) with respect to the electrodes (first electrode, second electrode) is not particularly limited. That is, the first light emitting layer and the second light emitting layer may be provided in this order from the first electrode side, or the second light emitting layer and the first light emitting layer may be provided in this order from the first electrode side.

In the display unit of the present invention, the first light emitting layer contains a first light emission dopant for emitting light of the first color and a second light emission dopant for emitting light of the second color different from the first color. Here, the light emitting positions of the first color and the second color in the first light emitting layer are different from each other in the thickness direction. Further, in the display unit of the present invention, the second light emitting layer contains a third light emission dopant for emitting light of the third color. Here, the third color is different from the first color and the second color. The light emitting position of the third color in the second light emitting layer is not particularly limited as long as an optical constructive condition (described later) is satisfied. Specifically, the light emitting position of the third color may be placed close to or away from the light emitting position of the first or second color.

In the present invention, the optical length in the thickness direction between the first electrode and the light emitting position satisfies a resonance condition, that is, an optical constructive interference condition, regarding at least two of the three kinds of colors (first color, second color, and third color). Preferably, the optical length in the thickness direction between the first electrode and the light emitting position satisfies a resonance condition, regarding all the three kinds of colors.

Further, in the present invention, a light converting member such as a color filter may be provided on the organic light emitting device to change the properties of light (spectra of light, color, etc.) output from the organic light emitting device.

The display unit of the present invention is hereinafter described specifically with reference to the drawings. Note that, the present invention is not limited by an embodiment described below.

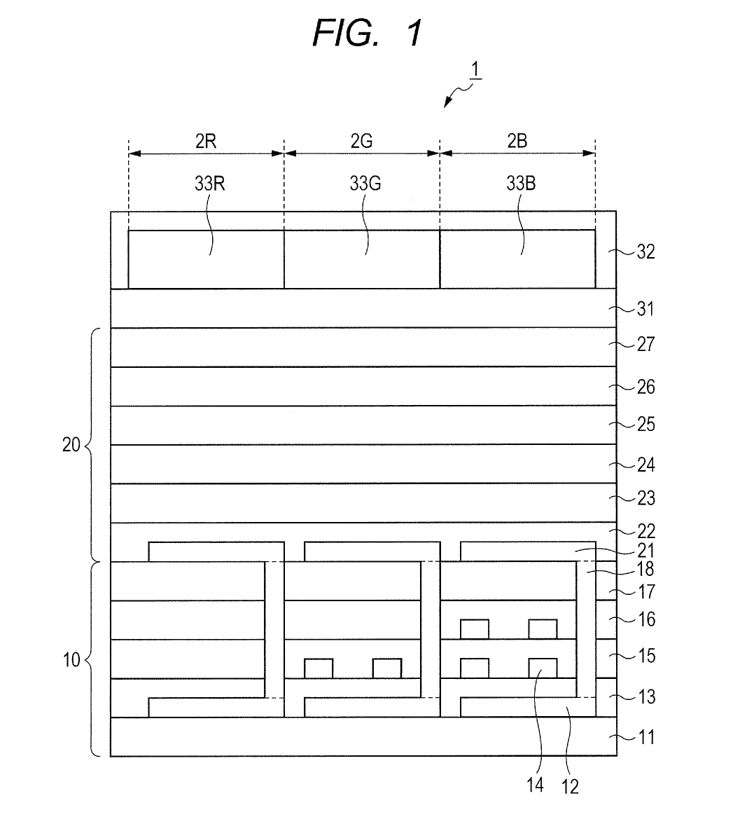

FIG. 1 is a schematic cross-sectional view illustrating an exemplary display unit according to the embodiment of the present invention. In a display unit 1 of FIG. 1, a first electrode 21 is provided for each pixel on a substrate 10, and an organic light emitting device 20 is provided on the first electrode 21. The display unit 1 of FIG. 1 includes a red pixel 2R for outputting a red color, a green pixel 2G for outputting a green color, and a blue pixel 2B for outputting a blue color.

In the display unit 1 of FIG. 1, the substrate 10 includes drive circuits 12 provided on a base 11. Each drive circuit 12 is covered with an interlayer insulating layer 13 and is electrically connected to a lower electrode (described later) through a contact hole 18 provided in the interlayer insulating layer 13.

On the interlayer insulating layer 13, wiring 14 for supplying a signal and electric power to the drive circuit 12 is provided in accordance with a circuit layout. The wiring 14 does not need to be provided for each pixel, and for example, as illustrated in FIG. 1, the wiring 14 may not be provided for the red pixel 2R. The wiring 14 is covered with an interlayer insulating layer 15. In the present invention, the wiring 14 may be stacked with an interlayer insulating layer interposed therebetween. For example, as in the blue pixel 2B of FIG. 1, the wiring 14 may be provided on two layers. In the case where the wiring 14 is stacked, every time the wiring 14 is formed, the wiring 14 is covered with the interlayer insulating layer (15, 16).

On the interlayer insulating layer 16 covering the wiring 14, a flattening layer 17 is provided for flattening the substrate 10 by filling unevenness generated when the drive circuit 12 and the wiring 14 are provided.

In the display unit 1 of FIG. 1, the organic light emitting device 20 is a laminate in which first electrodes (lower electrodes) 21, a hole transport layer 22, a first light emitting layer 23, a second light emitting layer 24, an electron transport layer 25, an electron injection layer 26, and a second electrode (upper electrode) 27 are laminated in this order. Note that, in the display unit of the present invention, the order of lamination of the two light emitting layers (first light emitting layer 23 and second light emitting layer 24) is not limited by the embodiment illustrated in FIG. 1. Specifically, the second light emitting layer 24 and the first light emitting layer 23 may be laminated in this order on the hole transport layer 22.

Further, in the present invention, the configuration of an organic compound layer provided between the first electrodes 21 and the second electrode 27 is not limited by the embodiment illustrated in FIG. 1, as long as at least two light emitting layers (first light emitting layer 23 and second light emitting layer 24) are provided. Examples of layers constituting the organic compound layer include a hole injection layer, a hole transport layer, an electron block layer, a hole block layer, an electron transport layer, and an electron injection layer, in addition to the light emitting layers.

Further, in the present invention, it is preferred that a layer be not interposed between the two light emitting layers (first light emitting layer 23 and second light emitting layer 24).

In the display unit 1 of FIG. 1, a sealing layer for sealing the organic light emitting device 20 is provided on the second electrode 27 constituting the organic light emitting device 20. On the sealing layer 31, a color converting member formed of a color filter substrate 32 and multiple kinds of color filters (33R, 33G, 33B) is provided.

As in the display unit 1 of FIG. 1, the organic light emitting device 20 constituting the display unit 1 of the present invention includes two light emitting layers (first light emitting layer 23 and second light emitting layer 24). In the present invention, the first light emitting layer 23 contains two kinds of light emission dopants (first light emission dopant and second light emission dopant), and the second light emitting layer 24 contains one kind of light emission dopant (third light emission dopant). As described above, the three kinds of light emission dopants have different emission colors, and hence, when the organic light emitting device 20 is allowed to emit light, emission light containing light beams of at least three different colors is obtained. Specifically, the three colors are emitted simultaneously, and hence, light output from each organic light emitting device 20 is light of color in which three emission colors are synthesized (for example, white light).

In the display unit of the present invention, an optical interference condition based on emission colors of the three kinds of light emission dopants is paid attention to. Specifically, in the present invention, the organic compound layer included in the organic light emitting device 20 formed in the display unit 1 is continuously provided in all the organic light emitting devices 20, in other words, the organic compound layers are formed of the same material with the same thickness in all the organic light emitting devices. In this manner, an optical constructive condition in optical interference is satisfied with respect to multiple emission colors. Note that, “the same” as used herein allows an error in a range of ±5%.

First, the optical interference condition is described. In the organic light emitting device 20, when an optical length L satisfies the following Expression (1), an optical constructive condition in optical interference can be used.

$$λ = \frac{2 L}{( m - \frac{φ t}{2 π} )} \qquad ( 1 )$$

In Expression (1), A is a resonance wavelength, L is an optical length, φt is a sum (rad) of phase shifts when emission light is reflected on the upper and lower electrodes, and m is a positive integer.

The optical length L in Expression (1) is represented by a sum (n₁d₁+n₂d₂+ . . . ) of products nd of a refractive index n of each layer, which is present in an area from a light emitting region in the light emitting layer to a reflective layer, and a thickness d thereof. In the case where the second electrode 27 is formed of a reflective semi-transparent electrode layer, light output from the light emitting layer can be resonated between the first electrode 21 and the second electrode 27. In this case, a sum of products of the refractive index n of each layer between the first electrode 21 and the second electrode 27 and the thickness d thereof can be defined as an optical length L.

It is desired that m be an integer. Note that, m does not need to be strictly defined as an integer, as long as an optical constructive condition in optical interference is satisfied, and an error in a range of ±10% with respect to an integer is allowable.

Further, regarding a phase shift φ at a reflective interface, it is assumed that, of two materials forming the reflective interface, a material placed on a side upon which light is incident is a medium I and the other material is a medium II, and respective optical constants are (n₁, k₁) and (n₂, k₂). Then, the phase shift φ can be represented by the following Expression (2). The optical constants can be measured with, for example, a spectroscopic ellipsometer.

$$φ = 2 π - {tan}^{- 1} ( \frac{2 {n}_{1} {k}_{1}}{{n}_{1}^{2} - {n}_{2}^{2} - {k}_{2}^{2}} )$$

(where 0≦φ≦2π)

Table 1 shows calculation results of the optical length L satisfying an optical constructive condition of each color and the thickness d of the organic compound layer obtained based on Expression (1) where m is 1 and the resonance wavelength λ of each color is 450 nm, 520 nm, and 620 nm. For obtaining parameters of the thickness, the refractive index of the organic compound layer was set to be 1.8 and φt was set to be π(rad).

TABLE 1

| λ | | L | | d |
|---|---|---|---|---|
| [nm] | m | [nm] | n | [nm] |
| 450 | 1 | 113 | 1.8 | 62.5 |
| 520 | 1 | 130 | 1.8 | 72.2 |
| 620 | 1 | 155 | 1.8 | 86.1 |

It is understood from Table 1 that the optical length depends on the emission wavelength (resonance wavelength), and for example, as the emission wavelength becomes shorter, the optical length satisfying the optical constructive condition becomes shorter correspondingly.

On the other hand, combinations of three kinds of light emission dopants contained in the first light emitting layer 23 and the second light emitting layer 24 are theoretically as shown in Table 2.

TABLE 2

| | |
|---|---|
| First light | Second light |
| emitting layer | emitting layer |

| | | Emission | | Emission |
|---|---|---|---|---|
| | | color of | | color of |
| First | Second | first | Third | second |
| light | light | light | light | light |
| emission | emission | emitting | emission | emitting |
| dopant | dopant | layer | dopant | layer |
| Red | Green | Yellow | Blue | Blue |
| Red | Blue | Magenta | Green | Green |
| Green | Blue | Cyan | Red | Red |
| Green | Red | Yellow | Blue | Blue |
| Blue | Green | Cyan | Red | Red |
| Blue | Red | Magenta | Green | Green |

In the display unit of the present invention, the optical constructive condition in optical interference only needs to be satisfied in light beams of at least two kinds of colors, and there is no particular limit to the combination of the two kinds of colors. On the other hand, it is desired that the two kinds of light emission dopants (first light emission dopant and second light emission dopant) contained in the first light emitting layer 23 be carrier trap dopants that trap different carriers (electrons or holes). Thus, the light emitting positions of light beams of two colors by the two kinds of light emission dopants contained in the first light emitting layer 23 can be varied in the thickness direction.

Now, the function of the present invention is described with reference to the drawings, if required, by way of a specific example of a system in which the emission color of the first light emitting layer is yellow (red and green) and the emission color of the second light emitting layer is blue (including cyan).

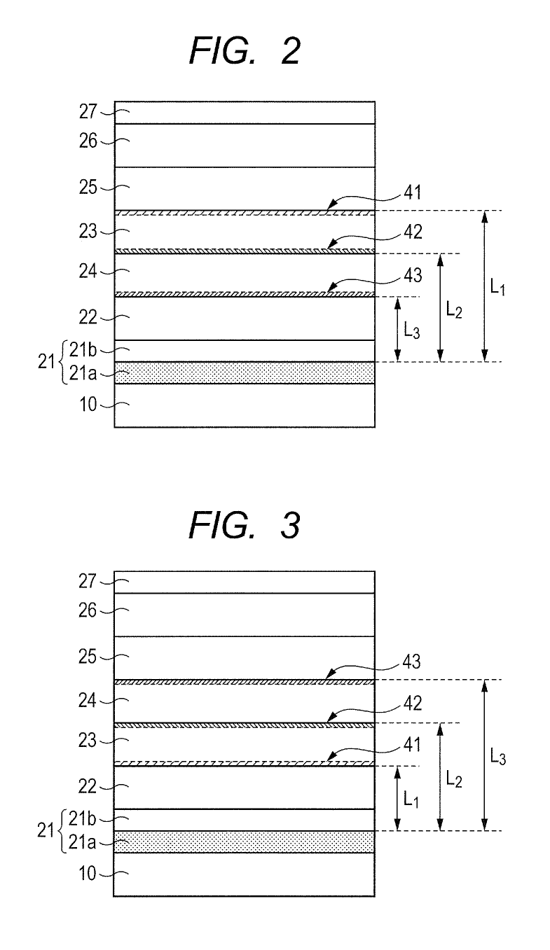

FIG. 2 is a schematic cross-sectional view illustrating a light emitting position of each light emission dopant in a thickness direction in the organic light emitting device 20 constituting the display unit 1 of FIG. 1. FIG. 2 illustrates a system in which the emission color of the first light emitting layer 23 is yellow (red and green), and the emission color of the second light emitting layer 24 is blue (including cyan). FIG. 2 illustrates a system in which the second light emitting layer 24 is used as a light emitting layer close to the first electrode 21. A specific example is hereinafter described in which the first light emission dopant and the second light emission dopant contained in the first light emitting layer 23 are a red dopant for emitting red light and a green dopant for emitting green light, and the third light emission dopant contained in the second light emitting layer 24 is a blue dopant for emitting blue light. The following description is merely one specific example of the present invention, and it can be determined freely which of the first to third light emission dopants is defined as which emission color dopant (blue (B) dopant, green (G) dopant, and red (R) dopant).

Respective light emitting regions 41 to 43 of the three kinds of light emission dopants are as illustrated in FIG. 2, depending on the conditions such as the kinds of carriers to be trapped. The light emitting region 41 is a region for light of the first color emitted by the first light emission dopant, the light emitting region 42 is a region for light of the second color emitted by the second light emission dopant, and the light emitting region 43 is a region for light of the third color emitted by the third light emission dopant. In FIG. 2, the first color is defined as red, the second color is defined as green, and the third color is defined as blue. It is assumed that the light emitting regions 41 to 43 are present in the vicinity of a laminate interface and have a width in the thickness direction of almost zero. In the case where, of the light emission dopants, there is a light emission dopant causing a width in the light emitting region, the thickness of each layer should be adjusted considering the width.

Optical lengths (L₁ to L₃) from the light emitting regions (41 to 43) present in the respective light emitting layers to the first electrode 21 (interface between a light transmission layer portion 21b and a reflective layer portion 21a of the first electrode) are set to be values shown in Table 1, for example. Then, the optical constructive condition in optical interference can be used for each light emission dopant. In the embodiment of FIG. 2, the following relationships hold between λ and L.

### L₁=1/4λ_{R}

### L₂=1/4λ_{G}

### L₃=1/4λ_{B}

### (λ_{R}=620 nm, λ_{G}=520 nm, λ_{B}=450 nm)

As dopants used as the first to third light emission dopants, any of a hole trap dopant and an electron trap dopant can be used. Here, considering the relationship between the carrier trap property of the light emission dopant and the light emitting region, in the case of the hole trap light emission dopant, a light emitting region is localized on the hole transport layer 22 side. On the other hand, in the case of the electron trap light emission dopant, a light emitting region is localized on the electron transport layer 25 side.

In the embodiment of FIG. 2, the first light emission dopant and the second light emission dopant contained in the first light emitting layer 23 are defined as an electron trap dopant and a hole trap dopant, respectively. On the other hand, the third light emission dopant contained in the second light emitting layer 24 is defined as a hole trap dopant. Then, as illustrated in FIG. 2, the light emitting region 41 of the first light emission dopant (red dopant) contained in the first light emitting layer 23 is present in the vicinity of the interface between the first light emitting layer 23 and the electron transport layer 25. Further, the light emitting region 42 of the second light emission dopant (green dopant) contained in the first light emitting layer 23 is present in the vicinity of the interface between the first light emitting layer 23 and the second light emitting layer 24. On the other hand, the light emitting region 43 of the third light emission dopant (blue dopant) contained in the second light emitting layer 24 is present in the vicinity of the interface between the second light emitting layer 24 and the hole transport layer 22.

Note that, in the embodiment of FIG. 2, the third light emission dopant is not limited by a hole trap dopant. In particular, when the optical constructive condition in optical interference is satisfied regarding red light and green light, the light emitting region of the third light emission dopant may be placed in the vicinity of the interface between the second light emitting layer 24 and the first light emitting layer 23 through use of an electron trap dopant as the third light emission dopant.

Considering the light emitting regions (41 to 43) of the respective colors illustrated in FIG. 2, when the respective thicknesses of the hole transport layer 22, the second light emitting layer 24, and the first light emitting layer 23 are set to be values shown in Table 3, the conditions of the optical length shown in Table 1 are satisfied.

TABLE 3

| | Thickness [nm] |
|---|---|
| First light emitting layer | 14 |
| Second light emitting layer | 10 |
| Hole transport layer | 63 |

There is no particular limit on the two kinds of colors which are to satisfy Expression (1), and at least two different colors of light beams output from the organic light emitting devices constituting the display unit may be determined. It is preferred to set the optical length so as to satisfy Expression (1) regarding light beams of three kinds of colors output from the organic light emitting devices constituting the display unit, because the effect of optical interference (optical constructive effect) can be utilized at maximum.

In the case where there is a difference in emission efficiency among light beams of three kinds of colors output from the organic light emitting devices, for example, when the optical length is set so as to satisfy Expression (1) regarding two kinds of emission colors having low emission efficiency, power consumption can be suppressed.

Further, the resonance wavelength can also be set appropriately so as to be shifted from the peak wavelength of light of each color for the purpose of adjusting chromaticity and viewing angle characteristics.

Thus, an organic compound layer is formed continuously in all the organic light emitting devices, and the optical constructive condition in optical interference can be satisfied simultaneously regarding light beams of multiple colors contained in light beams emitted from the organic light emitting devices.

The thickness of the organic compound layer does not need to be strictly matched in all the organic light emitting devices, and if the thickness is within a range of ±10% in all the light emitting pixels on the display unit, the thickness can be considered to be substantially the same.

FIG. 3 is a schematic cross-sectional view illustrating a modified example of FIG. 2. FIG. 3 illustrates a system in which the emission color of the first light emitting layer 23 is yellow (red and green), and the emission color of the second light emitting layer is blue (including cyan) in the same way as in the embodiment of FIG. 2. Here, FIG. 3 illustrates a system in which the first light emitting layer 23 is used as a light emitting layer close to the first electrode 21. A specific example is hereinafter described in which the first light emission dopant and the second light emission dopant contained in the first light emitting layer 23 are a green dopant and a red dopant, respectively, and the third light emission dopant contained in the second light emitting layer 24 is a blue dopant.

Light emitting regions 41 to 43 of the respective three kinds of colors contained in the first light emitting layer or the second light emitting layer are as illustrated in FIG. 3, depending on the conditions such as the kinds of carriers to be trapped. The light emitting region 41 is a region for light of the color emitted by the first light emission dopant, the light emitting region 42 is a region for light of the color emitted by the second light emission dopant, and the light emitting region 43 is a region for light of the color emitted by the third light emission dopant.

Optical lengths (L₁ to L₃) from the light emitting regions (41 to 43) present in the respective light emitting layers to the first electrode 21 are set appropriately. Then, the optical constructive condition in optical interference can be used for each light emission dopant. In the embodiment of FIG. 3, the following relationships hold between λ and L.

### L₁=1/4λ_{G}

### L₂=1/4λ_{R}

### L₃=3/4λ_{B}

### (λ_{R}=620 nm, λ_{G}=520 nm, λ_{B}=450 nm)

In the embodiment of FIG. 3, the first light emission dopant and the second light emission dopant contained in the first light emitting layer 23 are defined as a hole trap dopant and an electron trap dopant, respectively. On the other hand, the third light emission dopant contained in the second light emitting layer 24 is defined as an electron trap dopant. Then, as illustrated in FIG. 3, the light emitting region 41 of the first light emission dopant (green dopant) contained in the first light emitting layer 23 is present in the vicinity of the interface between the first light emitting layer 23 and the hole transport layer 22. Further, the light emitting region 42 of the second light emission dopant (red dopant) contained in the first light emitting layer 23 is present in the vicinity of the interface between the first light emitting layer 23 and the second light emitting layer 24. On the other hand, the light emitting region 43 of the third light emission dopant (blue dopant) contained in the second light emitting layer 24 is present in the vicinity of the interface between the second light emitting layer 24 and the electron transport layer 25.

Note that, in the embodiment of FIG. 3, the third light emission dopant is not limited by an electron trap dopant. In particular, when the optical constructive condition in optical interference is satisfied regarding red light and green light, the light emitting region of the third light emission dopant may be placed in the vicinity of the interface between the second light emitting layer 24 and the first light emitting layer 23 through use of a hole trap dopant as the third light emission dopant.

Then, considering the light emitting regions (41 to 43) of the respective colors illustrated in FIG. 3, the respective thicknesses of the hole transport layer 22, the first light emitting layer 23, and the second light emitting layer 24 are set appropriately.

Now, the constituent members of the display unit of the present invention are described. There is no particular limit on the base 11 used in the present invention, but metal, ceramics, glass, quartz, silicon, or the like is used. Further, a flexible substrate using a flexible sheet such as a plastic sheet can also be used.

The drive circuit 12 drives the organic light emitting device 20 to emit light. In the present invention, there is no particular limit on a constituent material for the drive circuit 12.

The interlayer insulating layers 13 (15, 16) are provided for electrically separating the drive circuit 12 from the wiring 14, the wiring 14 from the wiring 14, the drive circuit 12 from the first electrode 21, and the wiring 14 from the first electrode 21. The interlayer insulating layers 13 (15, 16) are formed of, for example, an inorganic insulating material such as silicon oxide (SiO₂).

The wiring 14 is a member provided so as to supply a signal and power and is formed of, for example, a conductive material such as aluminum (Al).

The flattening layer 17 is provided for filling unevenness generated when the drive circuit 12 and the wiring 14 are provided and flattening the substrate 10. Examples of the constituent material for the flattening layer 17 include an organic insulating material such as polyimide and an inorganic insulating material such as silicon oxide (SiO₂).

The first electrode 21 that is a lower electrode only needs to have a function as an anode and a function of reflecting emission light output from the light emitting layer, and the constituent material for the first electrode is not particularly limited. Examples of the constituent material for the first electrode 21 include simple metal such as aluminum (Al) and silver (Ag), a reflective metal material such as an alloy obtained by combining multiple kinds of simple metals, and a dielectric mirror in which multiple inorganic materials having different refractive indices are laminated. It is preferred to use a material having a high reflectance as the constituent material for the first electrode 21, because light extraction efficiency can be enhanced.

An organic compound used in the hole transport layer 22, the first light emitting layer 23, the second light emitting layer 24, or the electron transport layer 25 may be a low-molecular material or a high-molecular material. Alternatively, both the low-molecular material and the high-molecular material may be used to form the layers.

Examples of a light emitting material to be used in the first light emitting layer 23 and the second light emitting layer 24 include a fluorescent light emitting material and a phosphorescent light emitting material. However, the light emitting material is not particularly limited thereto. If required, a well-known material can be used. In the present invention, two kinds of light emission dopants are contained in the first light emitting layer 23, and one kind of light emission dopant is contained in the second light emitting layer 24. However, those which are known can also be used as the light emitting dopants.

Examples of the constituent material for the electron injection layer 26 include electron injection materials that are generally widely used, such as lithium fluoride, alkali metal, and alkaline-earth metal. Further, alkali metal, alkaline-earth metal, or a compound thereof may be contained in the electron-transporting organic compound material in an amount of 0.1 to tens of % to obtain an electron injection layer. At this time, it is preferred that the thickness of the electron injection layer 26 be set to be about 10 to 100 nm, because the layer or film formation damage of the second electrode 27, the sealing layer 31, and the color filters (33R, 33G, 33B) to be formed later can be alleviated.

In the display unit of the present invention, each layer that constitutes the organic compound layer is formed generally by vacuum deposition, ionized deposition, sputtering, plasma, or by dissolving an organic compound in an appropriate solvent to coat it by a known coating method (e.g., spin coating, dipping, casting, or ink-jet method).

The second electrode 27 that is an upper electrode has a function as a cathode. Examples of a constituent material for the second electrode 27 include a transparent metal oxide conductive film, specifically, a compound film of indium oxide and tin oxide (ITO) and a compound of indium oxide and zinc oxide (IZO). In the case of using a conductive film made of the transparent metal oxide for the second electrode 27, the thickness is set to be 10 nm or more and 100 nm or less, more preferably, 30 nm or more and 300 nm or less. This setting is preferred because both the reduction in a sheet resistance of the electrode and the high optical transmittance can be satisfied. It is preferred that the second electrode 27 be provided as a layer which is continuous to the organic light emitting device provided on the display unit.

The above-mentioned “transparent” refers to a transmittance with respect to visible light of 70% to 100%, and more specifically to an extinction coefficient k of 0.05 or less, preferably 0.01 or less. It is preferred that the extinction coefficient be as small as possible, from the viewpoint of suppressing the extinction of emission light while allowing the second electrode 27 to function as a transparent conductive layer.

Further, a semi-transparent metal thin film can also be used instead of the transparent metal oxide conductive film. In this case, specifically, simple metal such as silver, aluminum, magnesium, and calcium, or an alloy obtained by combining multiple kinds of simple metals is used. In particular, an alloy (silver magnesium) formed of silver and magnesium is preferred from the viewpoint of an electron injection property and reflectivity of emission light. Further, when the semi-transparent metal thin film is used, the thickness thereof is set to be about 2 nm to 50 nm. When the thickness is set to be 2 nm or more and 50 nm or less, a part of emission light passes through the film, which is preferred from the viewpoint of light extraction efficiency.

The sealing layer 31 is provided for sealing and protecting the organic light emitting device 20. Examples of a constituent material for the sealing layer 31 include light-transparent inorganic materials such as silicon oxide (SiO₂) and silicon nitride (SiN).

The color filter substrate 32 and the color filters (33R, 33G, 33B) constituting the color converting member are provided for modulating light emitted from the first light emitting layer 23 or the second light emitting layer 24 to any of three primary colors (red, green, and blue) and outputting the modulated light outside. Here, the color filters (33R, 33G, 33B) are members, for example, in which a pigment of desired color (red, green, or blue) is mixed in a resin. Further, the color filters (33R, 33G, 33B) of the respective colors are provided at positions corresponding to the organic light emitting devices, in other words, the first electrodes.

In the present invention, although three kinds of color filters are used, for example, as illustrated in the display unit 1 of FIG. 1, the number of kinds of color filters is not limited to three, and if required, can be decreased to two kinds or increased to four or more kinds.

The display unit of the present invention can be applied to various uses such as illumination, a display of electronic equipment, and a backlight for a display unit. Examples of the display of electronic equipment include displays of a TV receiver and a personal computer, a rear display portion of an imaging unit, a display portion of a mobile telephone, and a display portion of a portable game machine. Other examples of the application include a display portion of a portable music player, a display portion of a personal digital assistant (PDA), and a display portion of a car navigation system.

### EXAMPLES

Now, the present invention is described in detail by way of examples. Note that, the present invention is not limited by the examples herein.

### Example 1

The display unit illustrated in FIG. 1 was produced by the following method. Note that, in this example, a second light emitting layer and a first light emitting layer were formed in this order from a substrate 10 side.

A drive circuit 12 was formed on a silicon substrate (base 11), and thereafter silicon oxide (SiO₂) was formed on the base 11 and the drive circuit 12 to form an interlayer insulating layer 13. At this time, the thickness of the interlayer insulating layer 13 was set to be 300 nm.

Next, an aluminum alloy (AlNd) was formed on the interlayer insulating layer 13 by sputtering to form an AlNd film. At this time, the thickness of the AlNd film was set to be 60 nm. Then, the AlNd film was patterned to a desired shape by patterning through use of photolithography to form wiring 14 in a predetermined region in a green pixel 2G and a blue pixel 2B.

Next, silicon oxide (SiO₂) was formed on the interlayer insulating layer 13 and the wiring 14 to form an interlayer insulating layer 15. At this time, the thickness of the interlayer insulating layer 15 was set to be 300 nm. Then, an aluminum alloy (AlNd) was formed on the interlayer insulating layer 13 by sputtering to form an AlNd film. At this time, the thickness of the AlNd film was set to be 60 nm. Then, the AlNd film was patterned to a desired shape by patterning through use of photolithography to form wiring 14 in a predetermined region in the blue pixel 2B.

Next, silicon oxide (SiO₂) was formed on the interlayer insulating layer 15 and the wiring 14 to form an interlayer insulating layer 16. At this time, the thickness of the interlayer insulating layer 16 was set to be 300 nm. Then, a polyimide was formed on the interlayer insulating layer 16 to form a flattening layer 17. At this time, the thickness of the flattening layer 17 was set to be 500 nm. Next, a contact hole 18 for electrically connecting the drive circuit 12 to the first electrode 21 was formed in a predetermined region of the flattening layer 17. The substrate 10 produced by the above-mentioned process was used in the following process.

Next, an aluminum alloy (AlNd) was formed on the substrate 10 by sputtering to form an AlNd film. At this time, the thickness of the AlNd film was set to be 60 nm. Then, the AlNd film was patterned so as to remove regions other than those corresponding to the organic light emitting devices to be provided in pixels (2R, 2G, and 2B) by photolithography to form first electrodes 21 (lower electrodes). The first electrode 21 functions as an anode.

Next, a compound (I) represented by the following formula was formed by vacuum deposition, and a hole transport layer 22 was formed continuously on the substrate 10 and the first electrode 21. At this time, the thickness of the hole transport layer 22 was 63 nm, the vacuum degree during layer formation of the hole transport layer 22 was 1×10⁻⁴ Pa, and the deposition rate was 0.2 nm/sec.

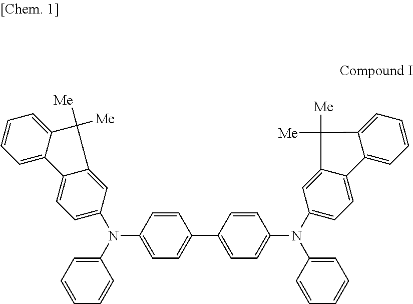 [SMILES: CC1(C)c2ccccc2-c2ccc(N(c3ccccc3)c3ccc(-c4ccc(N(c5ccccc5)c5ccc6c(c5)C(C)(C)c5ccccc5-6)cc4)cc3)cc21]

Next, a second light emitting layer 24 containing a hole trap dopant material exhibiting cyan emission light was formed to a thickness of 10 nm on the hole transport layer 22 by vacuum deposition. Then, a first light emitting layer 23 containing a hole trap dopant material exhibiting green light emission and an electron trap dopant material exhibiting red light emission was formed to a thickness of 14 nm on the second light emitting layer 24 by vacuum deposition.

Then, bathophenanthroline (Bphen) was formed as an electron transport layer 13 on the second light emitting layer 24 by vacuum deposition to form an electron transport layer 25. At this time, the thickness of the electron transport layer was set to be 6 nm, the vacuum degree during deposition was set to be 1×10⁻⁴ Pa, and the deposition rate was set to be 0.2 nm/sec.

Next, Bphen and Cs₂Co₃ were co-deposited (weight ratio: [Bphen]:[Cs₂Co₃]=90:10) on the electron transport layer 25 to form an electron injection layer 26 by vacuum deposition. Here, the thickness of the electron injection layer 26 was set to be 15 nm, the vacuum degree during deposition was set to be 3×10⁻⁴ Pa, and the deposition rate was set to be 0.2 nm/sec. Table 4 shows resonance wavelengths of light beams of respective colors in the light emitting pixels and values of m in Expression (1).

TABLE 4

| Resonance wavelength | |
|---|---|
| [nm] | m |
| 450 | 1 |
| 520 | 1 |
| 620 | 1 |

Next, the substrate having the electron injection layer 26 formed thereon was moved to a sputtering device in vacuum, and ITO was formed on the electron injection layer 26 by sputtering to form a second electrode 27. At this time, the thickness of the second electrode 27 was set to be 33 nm.

After that, the resultant substrate was moved to another CVD device in vacuum similarly, and a silicon nitride film was formed as a sealing layer 31. At this time, the thickness of the sealing layer 31 was set to be 2,000 nm.

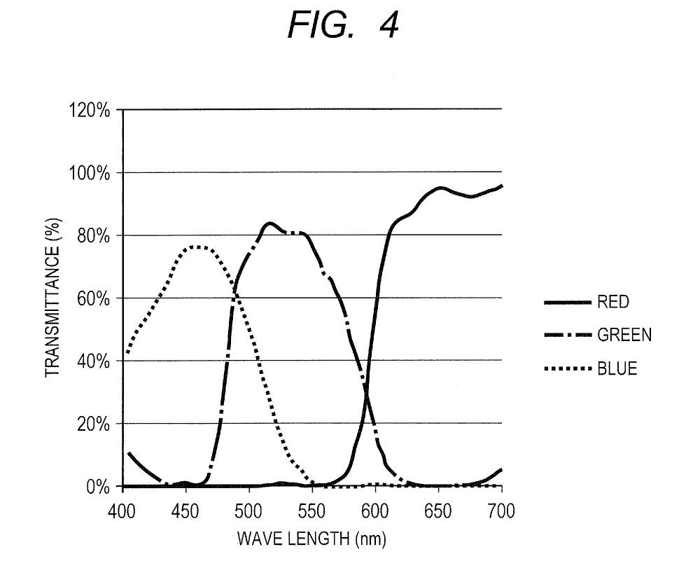

Then, a thin film made of an acrylic resin was formed to a thickness of 500 nm, and red, green, and blue color filters (33R, 33G, 33B) were produced in regions corresponding to the respective light emitting pixels. The thickness of the respective color filters (33R, 33G, 33B) was 2 μm. FIG. 4 is a view illustrating spectral characteristics of the respective color filters (33R, 33G, 33B) thus produced. After that, a thin film made of a transparent acrylic resin was formed to a thickness of 500 nm on the color filters (33R, 33G, 33B). Accordingly, a color filter substrate 32 having the color filters (33R, 33G, 33B) was produced. By allowing light emitted from the organic light emitting device to pass through the color filter, light of any one of red, green, and blue is output from each pixel.

A display unit was obtained through the above-mentioned process.

The organic light emitting device thus produced satisfies the optical constructive condition of each color (450 nm, 520 nm, 620 nm) at m=1 as shown in Table 1.

### Example 2

A display unit was produced by the same method as that of the display unit of Example 1, except that the thickness of the first light emitting layer 24 was set to be 48 nm in the display unit of Example 1. Table 5 shows resonance wavelengths in light emitting pixels of the respective colors constituting the produced display unit and values of m in Expression (1) in Example 2.

TABLE 5

| Resonance wavelength | |
|---|---|
| [nm] | m |
| 450 | 1 |
| 520 | 1 |
| 620 | 1.2 |

It is understood from Table 4 that, in the display device of Example 2, m is 1 at a resonance wavelength of 450 nm and 520 nm, and hence, the optical constructive condition is satisfied in blue and green colors. However, m is 1.2 at a resonance wavelength of 620 nm, and hence, it cannot be considered that the optical constructive condition is satisfied in a red color. Specifically, in this example, the optical constructive condition is satisfied in two emission colors (blue and green) of light emitting pixels of the respective colors.

### Comparative Example 1

A display unit was produced by the same method as that of Example 1, except that the thickness of the hole transport layer 22 was set to be 88 nm, the thickness of the first light emitting layer 23 was set to be 14 nm, and the thickness of the second light emitting layer 24 was set to be 19 nm in the display unit of Example 1. Table 6 shows resonance wavelengths in light emitting pixels of the respective colors constituting the produced display unit and values of m in Expression (1) in this comparative example.

TABLE 6

| Resonance wavelength | |
|---|---|
| [nm] | m |
| 450 | 1.2 |
| 520 | 1.2 |
| 620 | 1.2 |

It is understood from Table 5 that, in the display unit of this comparative example, m is 1.2 at a resonance wavelength of 450 nm, 520 nm, and 620 nm. Therefore, it cannot be considered that the optical constructive condition is satisfied in any emission color. Specifically, none of the three emission colors exhibited by the organic light emitting devices is set under the constructive condition.

The display units produced in Examples 1 and 2 and Comparative Example 1 were evaluated for a color reproduction range (NTSC ratio), power consumption, and viewing angle characteristics. Table 7 shows the results.

TABLE 7

| | Color reproduction | |
|---|---|---|
| | range | Power consumption |
| | [%] | [W] |
| Example 1 | 71 | 100* |
| Example 2 | 70 | 121* |
| Comparative | 57 | 390* |
| Example 1 | | |

*relative value in case where display unit of example 1 is set to be 100

It is understood from Table 7 that the display unit of the present invention has a wide color reproduction range and low power consumption, compared with the display unit of Comparative Example 1 in which the optical constructive condition is not set in any emission color.

Further, the following is found from Table 7. Specifically, the display unit of Example 1 in which the optical constructive condition is satisfied in all the emission colors has more satisfactory emission characteristics (color reproduction range, power consumption), compared with the display unit of Example 2 in which the color constructive condition is satisfied in two of the three kinds of emission colors.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-215069, filed Sep. 29, 2011, which is hereby incorporated by reference herein in its entirety.

What is claimed is:

1. A display unit, comprising multiple organic light emitting devices on a substrate,
wherein each of the organic light emitting devices includes a first electrode, a second electrode, and an organic compound layer which is sandwiched between the first electrode and the second electrode and includes at least a first light emitting layer and a second light emitting layer,
wherein the first light emitting layer contains a first light emission dopant for emitting light of a first color and a second light emission dopant for emitting light of a second color different from the first color, and a light emitting position of the light of the first color is different from a light emitting position of the light of the second color in a thickness direction,
wherein the second light emitting layer contains a third light emission dopant for emitting light of a third color different from the first color and the second color,
wherein the third light emission dopant is different from the first light emission dopant and the second light emission dopant in an emission color and a light emission spectrum, and
wherein an optical length from the first electrode to the light emitting position satisfies a resonance condition regarding light beams of at least two colors of the first color, the second color, and the third color.

2. The display unit according to claim 1, wherein the optical length from the first electrode to the light emitting position of light of each of the first color, the second color, and the third color satisfies a resonance condition regarding light beams of the first color, the second color, and the third color.

3. The display unit according to claim 1, further comprising a light converting member provided on the organic light emitting devices.

4. The display unit according to claim 1, wherein the first light emission dopant comprises an electron trap dopant, and the second light emission dopant comprises a hole trap dopant.

5. The display unit according to claim 4, wherein the third light emission dopant comprises a hole trap dopant.

6. The display unit according to claim 4, wherein the third light emission dopant comprises an electron trap dopant.

7. The display unit according to claim 5,
wherein the each of the organic light emitting devices has a structure in which the first electrode, a hole transport layer, the second light emitting layer, the first light emitting layer, an electron transport layer, and the second electrode are laminated in this order from the substrate side, the first color is red, the second color is green, and the third color is blue,
wherein an optical length from an interface between the first light emitting layer and the second light emitting layer to a reflective surface of the first electrode satisfies a resonance condition regarding the light of the second color, and
wherein an optical length from an interface between the second light emitting layer and the hole transport layer to the reflective surface of the first electrode satisfies a resonance condition regarding the light of the third color.

8. The display unit according to claim 7, wherein an optical length from an interface between the first light emitting layer and the electron transport layer to the reflective surface of the first electrode satisfies a resonance condition regarding the light of the first color.

9. The display unit according to claim 6,
wherein the each of the organic light emitting devices has a structure in which the first electrode, a hole transport layer, the first light emitting layer, the second light emitting layer, an electron transport layer, and the second electrode are laminated in this order from the substrate side, the first color is red, the second color is green, and the third color is blue,
wherein an optical length from an interface between the first light emitting layer and the hole transport layer to a reflective surface of the first electrode satisfies a resonance condition regarding the light of the second color, and
wherein an optical length from an interface between the second light emitting layer and the electron transport layer to the reflective surface of the first electrode satisfies a resonance condition regarding the light of the third color.

10. The display unit according to claim 9, wherein an optical length from an interface between the first light emitting layer and the second light emitting layer to the reflective surface of the first electrode satisfies a resonance condition regarding the light of the first color.

11. A display unit, comprising multiple organic light emitting devices on a substrate,
wherein each of the organic light emitting devices has a structure in which a first electrode, a hole transport layer, a second light emitting layer, a first light emitting layer, an electron transport layer, and a second electrode are laminated in this order from the substrate side,
wherein the first light emitting layer contains a first light emission dopant for emitting light of a first color and a second light emission dopant for emitting light of a second color different from the first color,
wherein the second light emitting layer contains a third light emission dopant for emitting light of a third color different from the first color and the second color,
wherein the first light emission dopant comprises an electron trap dopant, and the second light emission dopant and the third light emission dopant comprise a hole trap dopant,
wherein an optical length from an interface between the first light emitting layer and the second light emitting layer to a reflective surface of the first electrode satisfies a resonance condition regarding the light of the second color, and
wherein an optical length from an interface between the second light emitting layer and the hole transport layer to the reflective surface of the first electrode satisfies a resonance condition regarding the light of the third color.

12. The display unit according to claim 11, wherein an optical length from an interface between the first light emitting layer and the electron transport layer to the reflective surface of the first electrode satisfies a resonance condition regarding the light of the first color.

13. The display unit according to claim 12, wherein the first color is red, the second color is green, and the third color is blue.
